(19) United States
(12) Patent Application Publication
(10) Pub. No.: US 2025/0308968 A1
(43) Pub. Date: Oct. 2, 2025

(54) ARC REDUCTION USING UNREFERENCED FLOATING POWER SUPPLIES

(71) Applicant: Applied Materials, Inc., Santa Clara, CA (US)

(72) Inventors: Bryan Liao, Sunnyvale, CA (US); Edward P. Hammond, Hillsborough, CA (US); Dmitry A. Dzilno, Sunnyvale, CA (US); Liliya I. Krivulina, Santa Clara, CA (US); Tsutomu Tanaka, Santa Clara, CA (US); Ruiyun Huang, Santa Clara, CA (US); Jun Feng, Santa Clara, CA (US); Dan Zhu, Pleasanton, CA (US); Yuxing Zhang, San Jose, CA (US)

(73) Assignee: Applied Materials, Inc., Santa Clara, CA (US)

(21) Appl. No.: 18/617,280

(22) Filed: Mar. 26, 2024

(51) Int. Cl. H01L 21/683; C23C 16/458; C23C 16/509; H01J 37/32

(52) U.S. Cl. CPC H01L 21/6833; C23C 16/4586; C23C 16/509; H01J 37/32082; H01J 37/32715; H01J 2237/2007; H01J 2237/3321

(57) ABSTRACT

Electrostatic chucks are used to provide a clamping force between the substrate and the pedestal during semiconductor processes. However, charge buildup on the chuck electrodes and/or the substrate may cause damaging current arcs to occur as excess charge finds new pathways to the system ground. This technology uses floating power sources for the electrostatic chuck that are electrically isolated from the system ground. The power sources for the positive and negative electrodes in the pedestal may be connected together, and the typical ground connection between the power supplies can be removed. Floating and connected power supplies create a single current path that balances current between the two electrodes and eliminates free current paths to the system ground. This greatly reduces the likelihood of current arcs from the electrostatic chuck.

### TECHNICAL FIELD

This disclosure generally describes methods and systems for powering an electrostatic chuck in a semiconductor processing system. More specifically, this disclosure describes floating power supplies for an electrostatic chuck to reduce arcing.

### BACKGROUND

Semiconductor processing systems enable the precise manufacturing of electronic devices with intricate functionalities. These systems involve complex procedures such as etching, deposition, and lithography, for creating devices with specific characteristics. However, one persistent challenge in semiconductor processing is the occurrence of current arcs, which are undesirable electrical discharges between components that can lead to device damage, reduced yields, and increased manufacturing costs. Current arcs can arise from various sources including equipment malfunction, contamination, or improper handling, posing a significant hurdle in maintaining production efficiency and product quality.

Efforts to mitigate current arcs have involved the implementation of sophisticated monitoring and control systems, as well as the development of specialized materials and processing techniques. Nevertheless, existing solutions fall short in providing comprehensive protection against current arcs in different semiconductor processing environments. Addressing this challenge requires innovative approaches that not only detect and suppress current arcs effectively but also ensure minimal disruption to production processes. Thus, there is a need for improved systems and methods reducing the probability of current arcs during semiconductor processes. These and other needs are addressed by the present technology.

### SUMMARY

In some embodiments, a semiconductor processing chamber may include a pedestal configured to support a substrate during a semiconductor process. The pedestal may include a first electrode and a second electrode for a electrostatic chuck (ESC). The processing chamber may also include a chamber body that may enclose the pedestal to form a processing region in which the semiconductor process may be performed. The chamber body may be electrically connected to a system ground. The processing chamber may additionally include a first power source for the ESC that may be electrically connected to the first electrode. The first power source and the first electrode may be electrically isolated from the system ground. The processing chamber may further include a second power source for the ESC that may be electrically connected to the second electrode. The second power source and the second electrode may be electrically isolated from the system ground.

In some embodiments, an electrostatic chuck may include a first electrode and a second electrode embedded in a pedestal configured to support a substrate during a semiconductor process. The electrostatic chuck may also include a first power source including a positive output that may be electrically connected to the first electrode, and a negative output. The electrostatic chuck may additionally include a second power source including a negative output that may be electrically connected to the second electrode, and a positive output that may be electrically connected to the negative output of the first power source. A connection between the positive output of the second power source and the negative output of the first power source may be floating relative to a system ground.

In some embodiments, a semiconductor processing chamber may include a pedestal configured to support a substrate during a semiconductor process. The pedestal may include a first electrode for a electrostatic chuck (ESC). The semiconductor processing chamber may also include a radio-frequency (RF) RF ground that may ground RF power provided to a plasma in the semiconductor processing chamber. The semiconductor processing chamber may additionally include a first power source for the ESC that may provide a DC chucking voltage to the first electrode. The semiconductor processing chamber may further include a filter circuit that may be electrically connected to the first electrode, the RF ground, and the first power source for the ESC. The filter circuit may electrically isolate the first power source for the ESC from the RF ground.

In any embodiments, any and all of the following features may be implemented in any combination and without limitation. The semiconductor process may include a plasma-enhanced chemical vapor deposition (PECVD) process to deposit a film on the substrate. The semiconductor process may include depositing a carbon-based material on the substrate. The processing chamber may include a top-feed RF power supply that provides RF power to a plasma in the processing region, where the RF power may be grounded through the first electrode and/or the second electrode. The processing chamber may include a bottom-feed RF power supply that provides RF power to a plasma in the processing region, where the RF power may be provided through the first electrode and/or the second electrode. The semiconductor process may be performed at a temperature of between about 500° C. and about 700° C. The processing region may be free of current arcs from the first electrode, the second electrode, and the substrate during the semiconductor process. A connection between the positive output of the second power source and the negative output of the first power source may include a voltage offset that equalizes current through the first electrode and the second electrode resulting from a bias induced on the substrate. The electrostatic chuck may form a continuous current path from the first power source, to the first electrode, to the substrate, to the second electrode, to the second power source, and back to the first power source. The continuous current path need not be connected to any free current paths to the system ground. The first electrode and the second electrode may form a bipolar electrostatic chuck. The first power source may provide a positive voltage to the first electrode, and the second power source may provide an equal and opposite negative voltage to the second electrode. The filter circuit may be also electrically connected to an RF power supply that provides the RF power to the plasma through the first electrode. The filter circuit may isolate the RF power supply from the first power source for the ESC. The filter circuit may isolate the first power source for the ESC from the RF ground through a capacitor with a capacitance greater than about 15 nF. The filter circuit may isolate the first power source for the ESC from the RF ground through a resistor with a resistance greater than about 1 MΩ. The first power source for the ESC may provide greater than or about 1000 VDC to the first electrode for the ESC. The first power source for the ESC may provide about 1500 VDC to the first electrode for the ESC.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

FIG. 1 illustrates a cross-sectional view of a processing chamber, according to some embodiments.

FIG. 2 illustrates an example of a processing chamber with grounded power supplies, according to some embodiments.

FIG. 3 illustrates a processing chamber with floating power supplies, according to some embodiments.

### DETAILED DESCRIPTION

Electrostatic chucks are used to provide a clamping force between the substrate and the pedestal during semiconductor processes. However, charge buildup on the chuck electrodes and/or the substrate may cause damaging current arcs to occur as excess charge finds new pathways to the system ground. This technology uses floating power sources for the electrostatic chuck that are electrically isolated from the system ground. The power sources for the positive and negative electrodes in the pedestal may be connected together, and the typical ground connection between the power supplies can be removed. Floating and connected power supplies create a single current path that balances current between the two electrodes and eliminates free current paths to the system ground. This greatly reduces the likelihood of current arcs from the electrostatic chuck.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may include components and may be operated according to embodiments of the present technology before additional variations and adjustments to this system according to embodiments of the present technology are described.

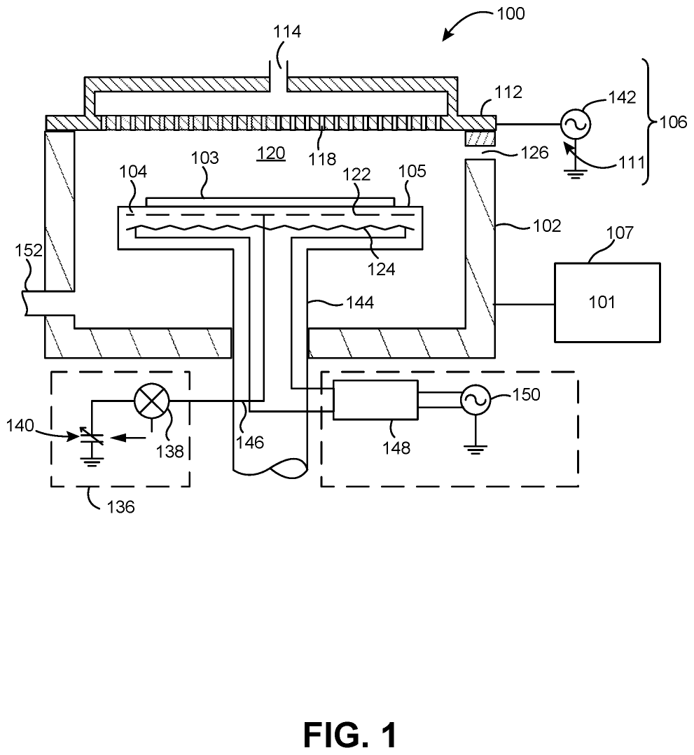

FIG. 1 shows a cross-sectional view of a processing chamber 100, according to some embodiments. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

Semiconductor processing chambers, such as the processing chamber 100 described above require tightly controlled environmental conditions in order to precisely deposit and/or etch complex and ever-shrinking circuit components. It is also important to limit the backside exposure of the substrate to the processing conditions that may result when there is a gap between the substrate and the pedestal. In order to ensure that the substrate does not move during the process, and to maintain a flat surface on the substrate that protects the backside of the substrate from exposure, electrostatic chucks are used to clamp the substrate to the pedestal. Electrostatic chucks apply a voltage to an electrode in the pedestal underneath the substrate. This voltage induces an opposing electric charge buildup on the substrate. These opposing electrostatic forces attract each other and provide a clamping force that securely holds the substrate on the pedestal during the semiconductor process.

One of the major challenges faced in systems using electrostatic chucks is their susceptibility to a phenomenon known as arcing, which may pose significant risk to manufacturing efficiency and quality of the resulting substrates. Arcing may refer to the sudden discharge of electrical energy between components within the chamber. Arcs can lead to localized heating, contamination, and substrate or chamber damage. Specifically, arcing occurs due to the excessive buildup of electrically charged particles, creating conditions that lead to electrical breakdown and discharge through current arcs. Current arcs are particularly problematic for electrostatic chucks since they are designed to create electrostatic fields between the pedestal and the substrate. For example, when the electric field strength surpasses the dielectric strength of any material between the charge and the system ground, a current discharge or arc may occur. For example, current arcs may occur between the substrate and the plasma, between the substrate and the electrodes in the pedestal, between the electrodes and a heating element, between the substrate and the chamber body, and so forth. The high temperatures generated during an arc can degrade materials in the chamber and the substrate as well as damage the substrate itself.

Traditional mitigation techniques for reducing arcing focus on optimizing process parameters such as power settings, process pressures/temperatures, gas compositions, and so forth. Other techniques involve insulation and shielding materials that attempt to increase the resistance along arc pathways. However, none of these techniques have been shown to completely eliminate arcing from semiconductor processing chambers.

The embodiments described herein solve these and other technical problems by greatly reducing the risk of a current arc from to the electrostatic chuck. Specifically, the circuit used to apply power to the electrostatic chuck electrodes may be completely isolated from the system ground. The power sources for the electrostatic chuck may be tied together to create a single current pathway through these power sources and the electrodes. Because the current in each leg of this current pathway must be equal, this greatly reduces the likelihood of excess charge leaving the circuit path and forming a current arc to another part of the chamber. The floating power supplies for the electrostatic chuck may maintain compatibility with RF sources that apply RF power to the plasma through a filter circuit with components sufficient to isolate the DC voltages of the electrostatic chuck from the system ground.

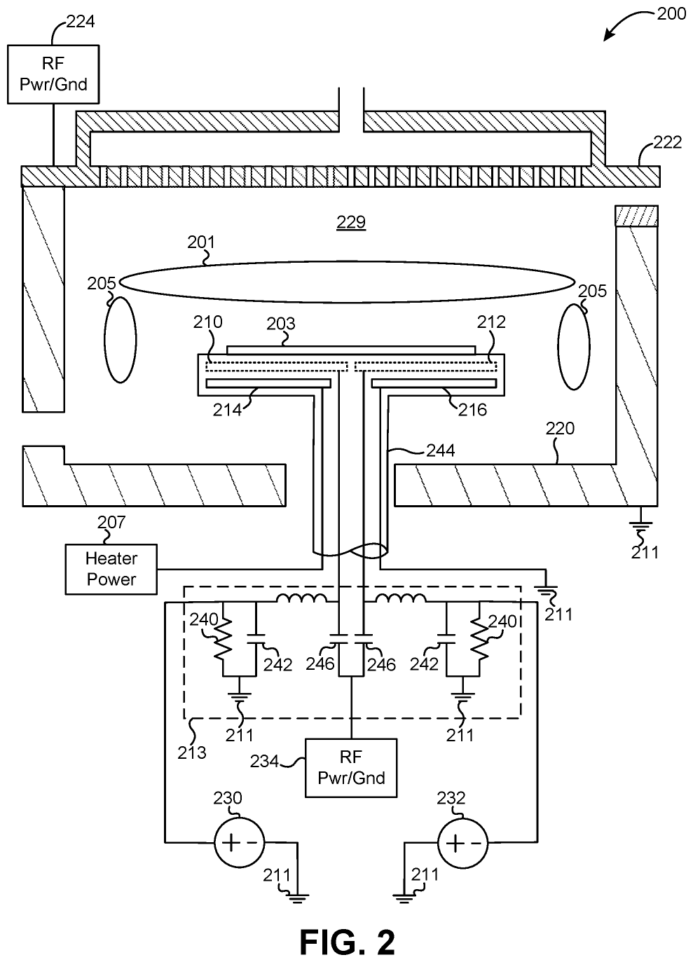

FIG. 2 illustrates an example of a processing chamber 200, according to some embodiments. The processing chamber 200 may be used to perform any type of semiconductor process, such as deposition, etch, and so forth. The semiconductor processes may or may not include a plasma. For example, the processing chamber 200 may be configured to perform deposition processes, such as a plasma-enhanced chemical vapor deposition (PECVD). Any type of film or material may be deposited on the substrate 203. For example, some processes may be configured to deposit a carbon-based material on the substrate 203. Depositing a carbon-based material may be particularly susceptible to current arcs as described above.

Deposition operations in the processing chamber 200 may be performed at fairly high temperatures, such as temperatures between about 500° C. and about 1000° C. For example, semiconductor processes may be performed at temperatures between about 500° C. and about 600° C., between about 600° C. and about 700° C., between about 700° C. and about 800° C., between about 800° C. and about 900° C., between about 900° C. and about 1000° C., and so forth. Processes may also be performed at any interval encompassed by the intervals described above (e.g., between about 500° C. and about 700° C.). Processes may also be performed at any specific temperature encompassed by the intervals described above (e.g., about 650° C.).

The processing chamber may include a pedestal 244 that is configured to support a substrate 203 during a semiconductor process. The pedestal 244 may include one or more electrodes for an electrostatic chuck (ESC). In this example, a bipolar ESC may use a first electrode 210 and a second electrode 212. These electrodes may be formed using any conductive material, and may have many different geometries. For example, some embodiments may use electrodes constructed from a conductive wire mesh that are shaped as hemispheres, with each hemisphere occupying approximate half of the area beneath the substrate 203. Other electrode geometries may also be used without limitation, including concentric circles, interlaced geometries, and other geometries that are not hemispherical in nature. The pedestal 244 may also include one or more heating elements 214, 216, which may be located below the first electrode 210 and the second electrode 212 in the pedestal 244.

In some embodiments, the electrodes for the ESC may also be used to provide RF power to a plasma 201 that is formed in a processing region 220 of the processing chamber 200. For example, the first electrode 210 and the second electrode 212 may be electrically connected to an RF power supply 234. The RF power supply 234 may provide RF power to the first electrode 210 and/or the second electrode 212 to power the plasma 201. A top plate or showerhead 222 of the processing chamber 200 may be electrically connected to an RF ground 224. This may be referred to as a bottom-feed RF system. Alternatively, the first electrode 210 and the second electrode 212 may be electrically connected to the RF ground, while the showerhead 222 is electrically connected to the RF power supply. This may be referred to as a top-feed RF system. Some embodiments may also use a dual-feed system where a first RF power supply providing a first frequency at a first power level (e.g., a high-power, high-frequency source) may be electrically connected to the showerhead and grounded through the electrodes, while a second RF power supply providing a second frequency at a second power level (e.g., a low-power, low-frequency source) may be electrically connected to the electrodes and grounded through the showerhead. The embodiments described herein are compatible with each of these different RF systems. The RF power supply 234 may provide RF power at frequencies commonly used by semiconductor processes, such as 350 kHz, 13.56 MHz, 27 MHz, 60 MHz to about 100 MHz, 2.5 GHZ, and/or other similar frequencies.

The processing chamber 200 may also include a chamber body 220 that encloses the pedestal 244 to form a processing region 229 in which the semiconductor process is performed. Generally, the chamber body may be electrically connected to a system ground 211. Generally, the system ground 211 will be the same as, or electrically connected to, the RF ground 224.

Leads for the different pedestal components, including the one or more heating elements 214, 216 and the ESC electrode, may be routed through a shaft of the pedestal 244. The one or more heating elements 214, 216 may be electrically connected to a heater power supply 207 and grounded to the system ground 211. When used to provide RF power, the ESC electrodes may also be connected to the RF power supply 234 (or alternatively to an RF ground) through decoupling capacitors 246 that filter DC voltages and protect the RF power supply 234. The first electrode 210 and the second electrode 212 may also be connected to a first power source 230 for the ESC and a second power source 232 for the ESC, respectively. A filter circuit 213 may filter out the RF signals while passing the DC signals to protect the power sources 230, 232 from the RF power for the plasma.

Chucking voltages may range from between about 500 VDC to about 2000 VDC, and some embodiments may use chucking voltages in excess of 1000 VDC. For example, the chucking voltage may range from between about 500 VDC to about 600 VDC, between about 600 VDC to about 700 VDC, between about 700 VDC to about 800 VDC, between about 800 VDC to about 900 VDC, between about 900 VDC to about 1000 VDC, between about 1000 VDC to about 1100 VDC, between about 1100 VDC to about 1200 VDC, between about 1200 VDC to about 1300 VDC, between about 1300 VDC to about 1400 VDC, between about 1400 VDC to about 1500 VDC, between about 1500 VDC to about 1600 VDC, between about 1600 VDC to about 1700 VDC, between about 1700 VDC to about 1800 VDC, between about 1800 VDC to about 1900 VDC, between about 1900 VDC to about 2000 VDC, and/or greater than about 2000 VDC. Chucking voltages may also be performed at any interval encompassed by the intervals described above (e.g., between about 1000 VDC and about 1500 VDC, greater than about 1000 VDC, etc.). Chucking voltages may also include any specific voltage encompassed by the intervals described above (e.g., about 1250 VDC). Note that these voltages described above may have both positive and negative magnitudes. For example, the first power source 230 may provide +1500 VDC to the first electrode 210, while the second power source 232 may provide −1500 VDC to the second electrode 212. Generally, these power sources may provide equal and opposite DC voltages to the pedestal 244 in an attempt to have equal current in both current pathways.

As illustrated in FIG. 2, the first power source 230 and the second power source 232 for the ESC are both electrically connected to the system ground 211. In this embodiment, the connection to the system ground 211 allows for multiple current pathways that may result in current arcs. For example, since the chamber body is also electrically connected to the system ground, a new current pathway from the first power source 230 through the first electrode 210 may be formed by a current arc between the first electrode 210 and a number of different pathways back to ground. For example, a current arc may discharge between the first electrode 210 and the one or more heating elements 214, 216. A current arc may discharge between the first electrode 210 and the plasma 201 above the substrate 203 and/or the plasma 205 to the side of the pedestal 244. Additionally, since an opposing charge may accumulate on the substrate 203, any of these current arcs may also discharge from the substrate to, e.g., the plasma 201, the chamber body 220, or any other component coupled to the system ground 211. As described above, these current arcs may cause damage the substrate 203 and/or the processing chamber 200. Since the separate current pathways through the first power source 230 and the second power source 232 are connected to the system ground 211, current arcs are more readily formed as the charge finds other pathways back to the system ground 211. In other words, separate DC current loops are possible to other portions of the processing chamber 200 back to the system ground 211.

Additionally, even when equal and opposite voltages are used by the first power source 230 and the second power source 232, the current may not be equal in the two current pathways through the first electrode 210 and the second electrode 212. For example, after a steady-state chucking voltage has been applied to the electrodes, asymmetry and imbalances in the physical design of the processing chamber 200, the substrate 203, and/or the placement of the substrate 203 on the pedestal 244 may cause imbalances in the current of the two leads to the electrodes for the ESC. Additionally, plasma conditions in the processing region may also induce a DC self-bias onto the substrate. The DC self-bias may cause an imbalance between the electrode chucking force and the current for each electrode. When the current is not balanced, the resulting chucking force may be imbalanced, and any current difference may be supplied through the system ground 211 as a current arc.

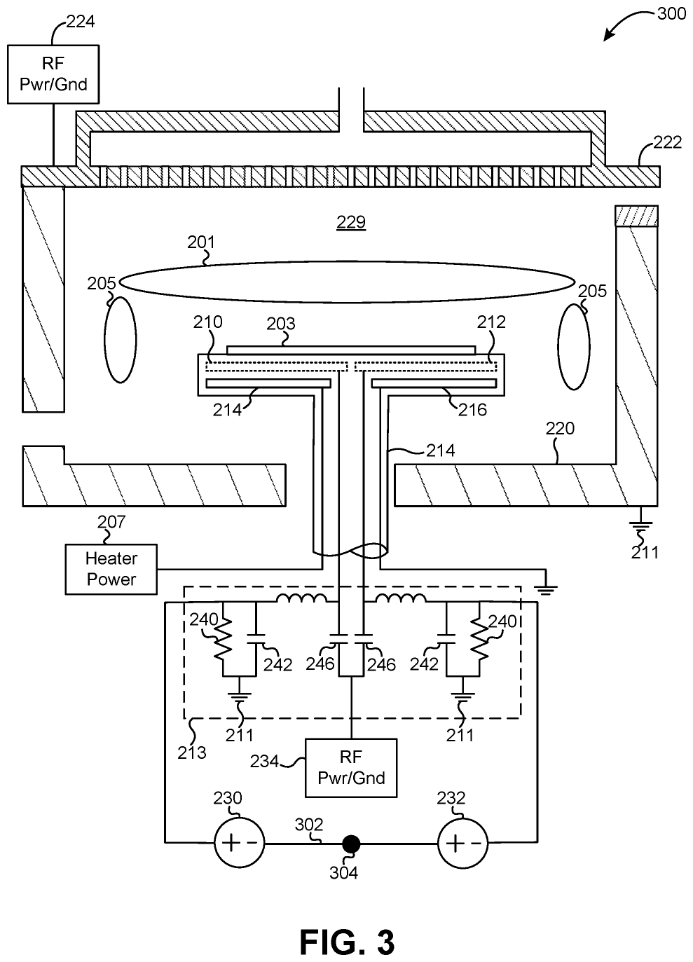

FIG. 3 illustrates a processing chamber 300 with floating power supplies, according to some embodiments. Instead of electrically connecting the first power source 230 and second power source 232 to the system ground 211, this system instead allows these power supplies and the ESC circuit as a whole to float relative to the system ground 211. For example, FIG. 3 illustrates how the first power source 230 may have a positive output and a negative output, with the positive output electrically connected to the first electrode 210. Similarly, the second power source 232 may also have a positive output a negative output, with the negative output electrically connected to the second electrode 212. In order to float these power sources relative to the system ground, a connection may be made between the positive output of the second power source 232 and the negative output of the first power source 230. These power supplies may be electrically isolated from the system ground 211.

As used herein, the term “electrically connected” implies a conductive connection without significant resistance (e.g., less than about 1 kΩ of resistance). The term “electrically isolated” implies a non-conductive connection with significant resistance (e.g., greater than about 1 MΩ of resistance).

By connecting the power supplies in this manner and removing the connection to the system ground 211, the electrostatic chuck forms a continuous current path from the first power source 230, to the first electrode 210, to the substrate 203, to the second electrode 212, to the second power source 232, and back to the first power source 230. Because of this single current path, the current in each ESC leads to/from the pedestal 244 will have a balanced, equal current. By eliminating the free connections to the system ground 211, it becomes far less likely that excess charge will exit this single, continuous current path through a damaging current arc.

When the first power source 230 provides a positive voltage to the first electrode 210, and the second power source 232 provides an equal and opposite negative voltage to the second electrode 212, the current through each of the ESC leads in the pedestal 244 will be equalized. However, the connection 302 between the positive output of the second power source 232 and the negative output of the first power source 230 may have a voltage offset that equalizes the current to the first electrode 210 and the second electrode 212. Specifically, a node 304 may have a non-zero voltage bias that adjusts dynamically during the semiconductor process to equalize the currents to the electrodes. In some embodiments, a separate voltage source controlled by the system controller may optionally be connected to the node 304 to adjust this bias and thereby adjust the current through the ESC leads. For example, if the plasma induces a negative bias on the wafer, this may cause a corresponding negative voltage on the node 304 to compensate for the induced bias on the wafer. Additionally, by tying the first power source 230 and second power source 232 together, this allows these power sources to provide different voltage values, since any current imbalance that would otherwise result will be balanced by the shifting the voltage of the node 304.

Although FIG. 3 illustrates two separate and distinct power sources for the ESC, some embodiments may alternatively use a single power source. For example, the first power source 230 may have the positive output connected to the first electrode 210 and the negative output connected to the second electrode 212. The first power source 230 may still float and be electrically isolated from the system ground 211.

As described above, some embodiments may share the first electrode 210 and/or the second electrode 212 between the electrostatic chuck and the RF system for powering the plasma 201. In order to maintain the isolation of the DC electrostatic chuck current pathway, the filter circuit 213 may be configured to provide DC isolation between the system ground 211 and the components of the electrostatic chuck. For example, a resistance 240 between the power supplies for the ESC and the ESC electrodes may be configured to have a resistance value sufficient to electrically isolate the DC voltage of the ESC from the system ground 211. For example, for ESC voltages up to about 2000 V, the resistance value can be determined by calculating the typical current of a current arc (e.g., about 5 mA) and using a resistance value large enough such any current through the resistor will be less than the current arc. For example, resistances greater than 1 MΩ may be sufficient in some designs to electrically isolate the system ground from the ESC in the filter circuit 213.

Similarly, capacitances 242 may also be designed with a capacitance value sufficient to isolate the system ground 211 from the ESC. For example, some embodiments may use capacitances with values between about 15 nF and about 25 nF for a bottom-feed RF system. For top-feed RF systems, the capacitances 242 and/or 246 may be tunable capacitors that may be adjusted based on the RF frequency of the plasma power source, along with other considerations.

The processing chamber 300 may be characterized as being substantially free of current arcs in the pedestal 244, in the processing region 229, and elsewhere resulting from the electrostatic chuck. For example, chucking voltages of up to +2000 V and −2000V may be used on the electrostatic chuck and generated by the ESC power sources without resulting in current arcs in the processing region 229. These voltages may be used in high temperatures, such as temperatures up to or in excess of about 1000° C. during PECVD deposition of carbon-based materials and/or other types of films.

As used herein, the terms “about” or “approximately” or “substantially” may be interpreted as being within a range that would be expected by one having ordinary skill in the art in light of the specification. For example, these terms may represent values within 10% of a stated value.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides example embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor processing chamber comprising:
a pedestal configured to support a substrate during a semiconductor process, wherein the pedestal comprises a first electrode and a second electrode for a electrostatic chuck (ESC);
a chamber body that encloses the pedestal to form a processing region in which the semiconductor process is performed, wherein the chamber body is electrically connected to a system ground;
a first power source for the ESC that is electrically connected to the first electrode, wherein the first power source and the first electrode are electrically isolated from the system ground; and
a second power source for the ESC that is electrically connected to the second electrode, wherein the second power source and the second electrode are electrically isolated from the system ground.

2. The semiconductor processing chamber of claim 1, wherein the semiconductor process comprises a plasma-enhanced chemical vapor deposition (PECVD) process to deposit a film on the substrate.

3. The semiconductor processing chamber of claim 1, wherein the semiconductor process comprises depositing a carbon-based material on the substrate.

4. The semiconductor processing chamber of claim 1, further comprising a top-feed RF power supply that provides RF power to a plasma in the processing region, wherein the RF power is grounded through the first electrode and/or the second electrode.

5. The semiconductor processing chamber of claim 1, further comprising a bottom-feed RF power supply that provides RF power to a plasma in the processing region, wherein the RF power is provided through the first electrode and/or the second electrode.

6. The semiconductor processing chamber of claim 1, wherein the semiconductor process is performed at a temperature of between about 500° C. and about 700° C.

7. The semiconductor processing chamber of claim 1, wherein the processing region is free of current arcs from the first electrode, the second electrode, and the substrate during the semiconductor process.

8. An electrostatic chuck comprising:
a first electrode and a second electrode embedded in a pedestal configured to support a substrate during a semiconductor process;
a first power source comprising a positive output that is electrically connected to the first electrode, and a negative output; and
a second power source comprising a negative output that is electrically connected to the second electrode, and a positive output that is electrically connected to the negative output of the first power source, wherein a connection between the positive output of the second power source and the negative output of the first power source is floating relative to a system ground.

9. The electrostatic chuck of claim 8, wherein a connection between the positive output of the second power source and the negative output of the first power source comprises a voltage offset that equalizes current through the first electrode and the second electrode resulting from a bias induced on the substrate.

10. The electrostatic chuck of claim 8, wherein the electrostatic chuck forms a continuous current path from the first power source, to the first electrode, to the second electrode, to the substrate, to the second power source, and back to the first power source.

11. The electrostatic chuck of claim 10, wherein the continuous current path is not connected to any free current paths to the system ground.

12. The electrostatic chuck of claim 8, wherein the first electrode and the second electrode form a bipolar electrostatic chuck.

13. The electrostatic chuck of claim 8, wherein the first power source provides a positive voltage to the first electrode, and the second power source provides an equal and opposite negative voltage to the second electrode.

14. A semiconductor processing chamber comprising:
a pedestal configured to support a substrate during a semiconductor process, wherein the pedestal comprises a first electrode for a electrostatic chuck (ESC);
a radio-frequency (RF) RF ground that grounds RF power provided to a plasma in the semiconductor processing chamber;
a first power source for the ESC that provides a DC chucking voltage to the first electrode; and
a filter circuit that is electrically connected to the first electrode, the RF ground, and the first power source for the ESC, wherein the filter circuit electrically isolates the first power source for the ESC from the RF ground.

15. The semiconductor processing chamber of claim 14, wherein the filter circuit is also electrically connected to an RF power supply that provides the RF power to the plasma through the first electrode.

16. The semiconductor processing chamber of claim 15, wherein the filter circuit isolates the RF power supply from the first power source for the ESC.

17. The semiconductor processing chamber of claim 14, wherein the filter circuit isolates the first power source for the ESC from the RF ground through a capacitor with a capacitance greater than about 15 nF.

18. The semiconductor processing chamber of claim 14, wherein the filter circuit isolates the first power source for the ESC from the RF ground through a resistor with a resistance greater than about 1 MΩ.

19. The semiconductor processing chamber of claim 14, wherein the first power source for the ESC provides greater than or about 1000 VDC to the first electrode for the ESC.

20. The semiconductor processing chamber of claim 14, wherein the first power source for the ESC provides about 1500 VDC to the first electrode for the ESC.
